(19) United States
(12) Patent Application Publication
(10) Pub. No.: US 2007/0296041 A1
(43) Pub. Date: Dec. 27, 2007

(54) SEMICONDUCTOR DEVICE AND METHOD OF MANUFACTURING THE SAME

(75) Inventors: Susumu TAMON, Kuwana (JP); Hiroaki Hazama, Yokkaichi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/769,508

(22) Filed: Jun. 27, 2007

(30) Foreign Application Priority Data
Jun. 27, 2006 (JP) 2006-176650

(51) Int. Cl. H01L 29/76

(52) U.S. Cl. 257/365

(57) ABSTRACT

A semiconductor device including a semiconductor substrate, a memory cell transistor formed in a memory cell region of the semiconductor substrate; a transistor formed in a peripheral circuit region of the semiconductor substrate and having an LDD (Lightly Doped Drain) structure; and the memory cell transistor has a same film thickness for an insulating film formed in a source/drain region and an insulating film formed or a gate electrode sidewall; and the transistor having the LDD structure is provided with a spacer insulating film on the gate electrode sidewall.

### CROSS-REFERENCE TO RELATED APPLICATIONS

This application is based upon and claims the benefit of priority from the prior Japanese Patent Application No. 2006-176650, filed on, Jun. 27, 2006 the entire contents of which are incorporated herein by reference.

### FIELD

The present disclosure is directed to a semiconductor device having a memory cell region having memory cell transistors and a peripheral circuit region having MOS transistors taking an LDD structure and a method of manufacturing such semiconductor device.

### BACKGROUND

Some nor-volatile semiconductor memory devices such as a NAND flash memory device employ transistors taking an LDD (Lightly Doped Drain) structure in their peripheral circuit region. Manufacturing process flow for such semiconductor devices is disclosed in JP H08-088288 A, for example.

The disclosed manufacturing steps involve forming diffusion regions in the transistors in the memory cell region as well as the transistors in the peripheral circuit region, whereafter silicon nitride film is formed over the entire surface and spacers are formed on the sidewalls of the gate electrodes. Then, heavily-doped diffusion regions are selectively formed in the transistors taking LDD structure by using the formed spacers as a mask.

In employing the manufacturing steps described in the aforementioned document, since the transistors in the memory cell region do not require LDD structure, the spacers formed in the sidewalls of the gate electrode may become an impediment in the processing step carried out afterwards. This is especially true in the memory cell region where further narrowing of spacing between the gate electrodes (higher aspect ratio) is required by stricter design rules. Under such condition, it becomes increasingly difficult to reliably fill inter-gate electrode gaps with interlayer insulating films. For instance, poor gap fill capability in filling interlayer insulating films between select gates may cause shorting of bit-lines which may result in a critical device failure.

The above manufacturing steps involve deposition of silicon nitride films serving as spacers on the sidewalls of the gate electrodes; whereas silicon nitride film or the semiconductor substrate is removed by anisotropic etch. Such presence/absence of silicon nitride film causes variance in the formation of barrier silicon nitride film in the subsequent process. Variance in incubation time of silicon oxide film and silicon nitride film in forming the silicon nitride film accelerates deposition rate of the barrier silicon nitride film deposited on the gate electrode sidewall as compared to the deposition rate of the same on the semiconductor substrate. Such variance in the condition in which the barrier silicon nitride film is formed may result in less silicon nitride deposition on the semiconductor substrate, thereby reducing its barrier capability.

Also, in case tungsten silicide (WSi) film is used as gate electrode material, unevenness is observed in the gate electrode sidewall surface due to thermal processing, or the like performed after forming the gate electrode. When the gate electrode takes such shape, accelerated deposition of silicon nitride film on the sidewalls facilitates silicon nitride deposition in openings defined between the gate electrodes, consequently narrowing the opening. This may further decelerate silicon nitride deposition on the semiconductor substrate.

In case only little or no barrier silicon nitride film is deposited due to the above described reasons, boron (B) or phosphorous (P) contained in BPSG or PSG of the interlayer insulating film formed in the backend process diffuse inside the silicon substrate, which in turn alters transistor characteristics to a considerable extent and may ultimately lead to malfunction.

Another concern is that in forming spacers on the gate electrode sidewalls, the semiconductor substrate may be etched by anisotropic etch performed after deposition of silicon nitride film. As for the regions where impurities have been doped in the diffusion layers of the transistors, etching of impurity diffusion layers may cause increase in resistance of the impurity diffusion layers, consequently leading to degradation of transistor characteristics such as reduction of transistor ON current, and in the worst case may prevent normal operation.

Thus, conventional process flow for fabricating LDD structure may introduce problems as described above to non-LDD transistors; especially in cell arrays subject to increasing integration and stricter design rules.

### SUMMARY

The present disclosure provides a semiconductor device having a memory cell region and a peripheral circuit region that restrains defective occurrences during the processing flow of the device even in forming transistors taking an LDD structure in the peripheral circuit region. The present disclosure also provides a method of manufacturing such semiconductor device.

In one aspect of the present disclosure, a semiconductor device includes a semiconductor substrate including an upper surface having a memory cell region and a peripheral circuit region; a memory cell transistor formed in the memory cell region of the semiconductor substrate, including a first gate electrode formed or the upper surface of the semiconductor substrate via a first gate insulating film and a first source/drain regions formed in the upper surface being adjacent to the first gate electrode; a peripheral transistor, having an LDD (Lightly Doped Drain) structure, formed in the peripheral circuit region of the semiconductor substrate, including a second gate electrode formed on the upper surface of the semiconductor substrate via a second gate insulating film and a second source/drain regions formed in the upper surface being adjacent to the second gate electrode; a first insulating film formed on a first sidewall of the first gate electrode, the first source/drain regions and a second sidewall of the second gate electrode; a second insulating film formed on the first sidewall, the first source/drain regions, the second sidewall via the first insulating film, respectively, and an interlayer insulating film formed on the second insulating film, the interlayer insulating film located adjacent to the first sidewall, wherein the second insulating film is formed on the second source/drain regions without the first insulating film.

In another aspect, a semiconductor device of the present disclosure includes a semiconductor substrate; a memory cell transistor formed in a memory cell region of the semiconductor substrate; a transistor formed in a peripheral circuit region of the semiconductor substrate and having an LDD (Lightly Doped Drain) structure; and the memory cell transistor has a same film thickness for an insulating film formed on source/drain regions and an insulating film formed on a gate electrode sidewall; and the transistor having the LDD structure is provided with a spacer insulating film on the gate electrode sidewall.

Yet, in another aspect, a method of manufacturing a semiconductor device of the present disclosure includes forming a gate electrode on a semiconductor substrate for each transistor in a memory cell region having memory cell transistors and a peripheral circuit region having transistors having an LDD structure; forming a diffusion region constituting source/drain regions on a portion of the semiconductor substrate of each transistor in the memory cell region and the peripheral circuit region; forming a first insulating film on the semiconductor substrate and a surface of each gate electrode; forming a spacer or a sidewall of the gate electrode by selectively processing a portion of the first insulating film formed in the transistor having the LDD structure; forming heavily-doped impurity diffusion region in a portion of the semiconductor substrate of the transistor having the LDD structure; forming a second insulating film on the semiconductor substrate and the surface of the gate electrode; and forming an interlayer insulating film.

### BRIEF DESCRIPTION OF THE DRAWINGS

Other objects, features and advantages of the present disclosure will become clear upon reviewing the following description of the embodiment of the present disclosure with reference to the accompanying drawings, in which,

FIG. 1 is a schematic cross sectional view of each transistor in a memory cell region and a peripheral circuit region illustrating a first embodiment of the present disclosure;

FIG. 2 is a schematic plan view corresponding to each configuration in FIG. 1;

FIG. 3 is a cross sectional view showing one phase of a manufacturing step;

FIG. 4 is a cross sectional view showing one phase of a manufacturing step (2^{nd} variation);

FIG. 5 is a cross sectional view showing one phase of a manufacturing step (3^{rd} variation);

FIG. 6 is a cross sectional view showing one phase of a manufacturing step (4^{th} variation);

FIG. 7 is a cross sectional view showing one phase of a manufacturing step (5^{th} variation);

FIG. 8 is a cross sectional view showing one phase of a manufacturing step (6^{th} variation);

FIG. 9 is a cross sectional view showing one phase of a manufacturing step (7^{th} variation);

FIG. 10 is a cross sectional view showing one phase of a manufacturing step (8^{th} variation);

FIG. 11 is a cross sectional view showing one phase of a manufacturing step (9^{th} variation);

FIG. 12 is a cross sectional view showing one phase of a manufacturing step (10^{th} variation);

FIG. 13 is a schematic cross sectional view illustrating an enlarged impurity diffusion region of the memory cell region;

FIG. 14 illustrates the second embodiment of the present disclosure and corresponds to FIG. 1;

FIG. 15 is a cross sectional view showing one phase of a manufacturing step;

FIG. 16 is a cross sectional view showing one phase of a manufacturing step (2^{nd} variation);

FIG. 17 is a cross sectional view showing one phase of a manufacturing step (3^{rd} variation);

FIG. 18 illustrates the third embodiment of the present disclosure and corresponds to FIG. 1;

FIG. 19 is a cross sectional view showing one phase of a manufacturing step;

FIG. 20 is a cross sectional view showing one phase of a manufacturing step (2^{nd} variation);

FIG. 21 is a cross sectional view showing one phase of a manufacturing step (3^{rd} variation);

FIG. 22 is a cross sectional view showing one phase of a manufacturing step (4^{th} variation);

FIG. 23 is a cross sectional view showing one phase of a manufacturing step (5^{th} variation);

FIG. 24 is a cross sectional view showing one phase of a manufacturing step (6^{th} variation); and

FIG. 25 is a cross sectional view showing one phase of a manufacturing step (7^{th} variation).

### DETAILED DESCRIPTION

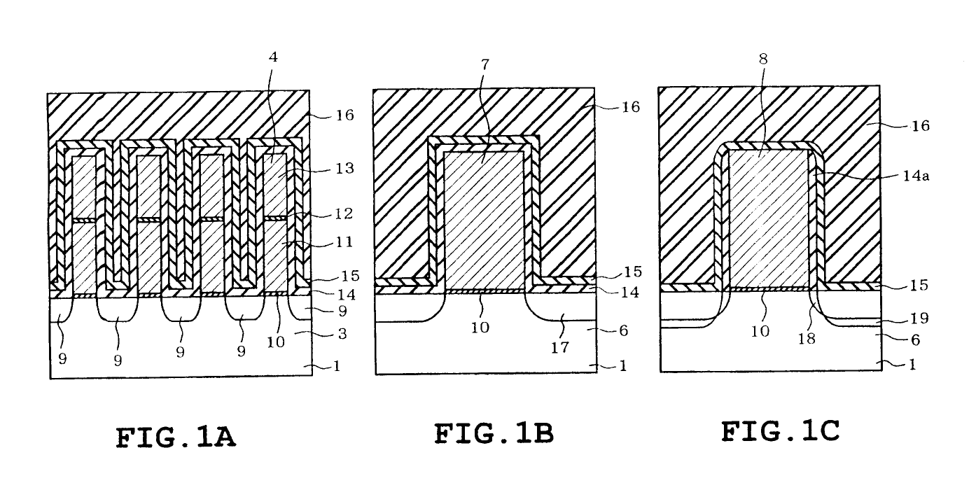

One embodiment applying the present disclosure to a NAND flash memory device will be described with reference to FIGS. 1 to 13.

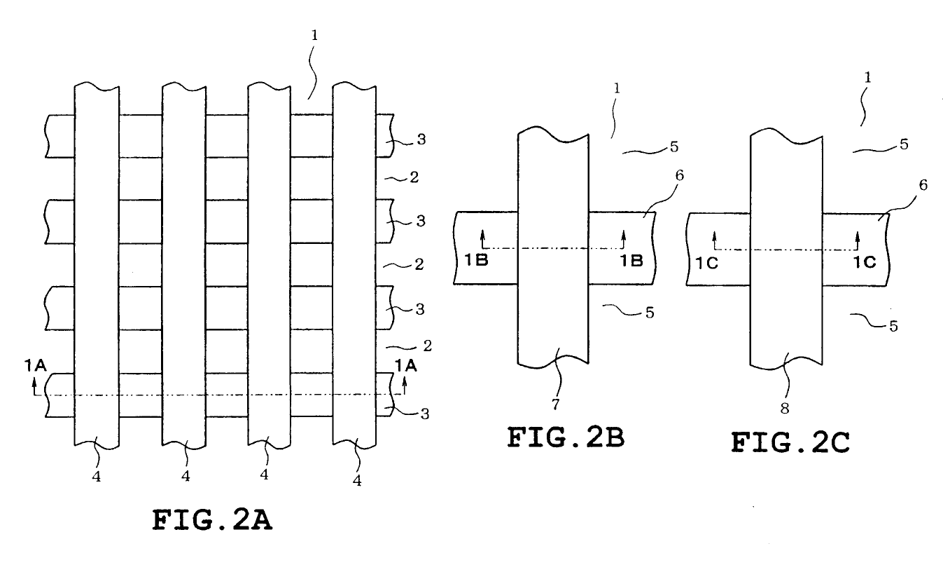

FIGS. 1 and 2 are schematic and planar views of each transistor in a memory cell region and a peripheral circuit region. FIG. 2A illustrates an array of memory cell transistors in the memory cell region, FIG. 2B illustrates a non-LDD transistor in the peripheral circuit region and FIG. 2C illustrates LDD transistors in the peripheral circuit region.

Referring to FIG. 2A, a silicon substrate 1 serving as a semiconductor substrate has STI (Shallow Trench Isolation) 2 serving as element isolation regions defined thereto at predetermined intervals, whereby active regions 3 serving as element forming regions are defined by the isolation. Gate electrodes 4 are formed so as to define perpendicular intersections with the active regions 3. A channel region is formed on the active region 3 at a portion intersecting the gate electrode 4. Source/drain regions are formed on both sides of the channel region to constitute a memory transistor.

Similarly, active regions 6 are defined by the STI 5 in FIGS. 2B and 2C and gate electrodes 7 and 8 are formed respectively so as to perpendicularly intersect the active region 6. A channel region is formed on the active region 6 at a portion intersecting the gate electrodes 7 and 8. Source/drain regions are formed on both sides of the channel region. Of note is that transistors in the peripheral circuit region (corresponding to a peripheral transistor) are formed in larger size than the memory transistors and include high-voltage types as well as low-voltage types. Also, transistors illustrated in FIG. 2C are LDD transistors as will be described afterwards.

FIGS. 1A to 1C are schematic cross sectional views taken along 1A-1A, 1B-1B, and 1C-1C of FIGS. 2A to 2C to schematically illustrate the cross sections of gate electrodes 4, 7 and 8 along the active regions 3 and 6. Referring to FIG. 1A, the active region 3 of the silicon substrate 1 serving as the semiconductor substrate has an impurity diffusion region 9 constituting the source/drain regions formed between the gate electrodes 4.

The gate electrode 4 takes a stacked configuration situated or the surface of the silicon substrate composed of the following elements listed in sequence from the bottom of the stack: a gate insulating film 10; a floating gate electrode 11; an inter-gate insulating film 12; and a control gate electrode 13. The gate electrode 4 illustrated in FIG. 2A is formed so as to transverse the STI 2; however, the floating gate electrode 11 is not formed on the STI 2 but is formed discontinuously whereas the inter-gate insulating film 12 and the control gate electrode 13 above it is formed continuously.

A silicon nitride film 14 for forming a spacer serving as a first insulating film and a barrier silicon nitride film 15 serving as a second insulating film are formed so as to cover the upper surface and the side surface of the gate electrode 4 and the exposed surface of the silicon substrate 1. An interlayer insulating film 16 is formed on the silicon nitride film 15 so as to fill the gaps between the gate electrodes 4, and the upper surface of the interlayer insulating film 16 is planarized.

Referring to FIG. 1B illustrating a non-LDD transistor in the peripheral circuit region, impurity diffusion regions 17 constituting the source/drain regions are formed on both sides of the gate electrode 7 of the active region 6 in the silicon substrate 1. The gate electrode 7 is formed via the gate insulating film 10. The silicon nitride film 14 for forming spacers and barrier silicon nitride film 15 are formed in a laminated configuration so as to cover the upper surface and the side surface of the gate electrode 7 and the exposed surface of the silicon substrate 1. The interlayer insulating film 16 is formed to fill the gaps between the gate electrodes 7 and the upper surface of the interlayer insulating film 16 is planarized.

Similarly, the LDD transistor illustrated in FIG. 1C has impurity diffusion regions 18 constituting the source/drain regions formed on both sides of the gate electrode 8 of the active region 6 in the silicon substrate 1 and heavily-doped impurity diffusion regions 19 corresponding to the LDD structure are formed thereto. The gate electrode 8 is formed via the gate insulating film 10. A spacer 14a is formed on the side surface of the gate electrode 8 by processing the nitride silicon film 14 and the barrier silicon nitride film 15 is laminated thereon so as to cover the gate electrode 8 and the spacer 14a. The interlayer insulating film 16 is formed on the silicon nitride film 15 so as to fill the gaps between the gate electrodes 8 and the upper surface of the interlayer insulating film 16 is planarized.

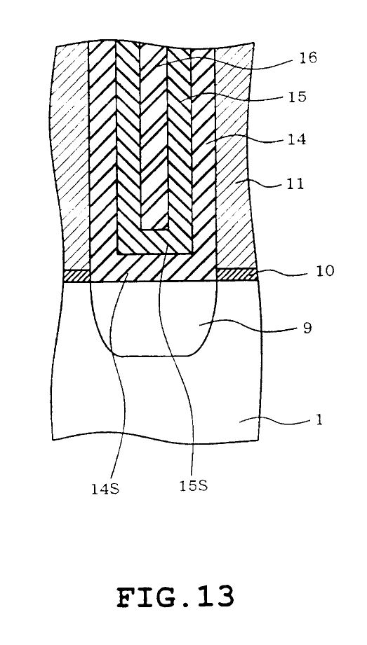

According to the above configuration, the spacer 14a is formed only for transistors employing the LDD structure illustrated in FIG. 1C, therefore transistors that do not employ the LDD structure have no spacers formed thereto. Thus, as illustrated in the enlarged view of the memory cell region in FIG. 13, silicon nitride film 14s remain on the sidewalls of the gate electrodes 4 and 7 and the exposed surface of the silicon substrate 1. This allows a silicon nitride film 15s to be formed in consistent thickness in the portion of the silicon substrate 1 as well when forming the barrier silicon nitride film 15 after forming the spacer 14a.

Thus, for transistors in the memory cell region, silicon nitride film 15 in consistent thickness is formed in the regions between the gate electrodes where aspect ratio is high. Thus, voids and lack of film thickness of the silicon nitride film 15 situated on the silicon substrate 1 can be eliminated.

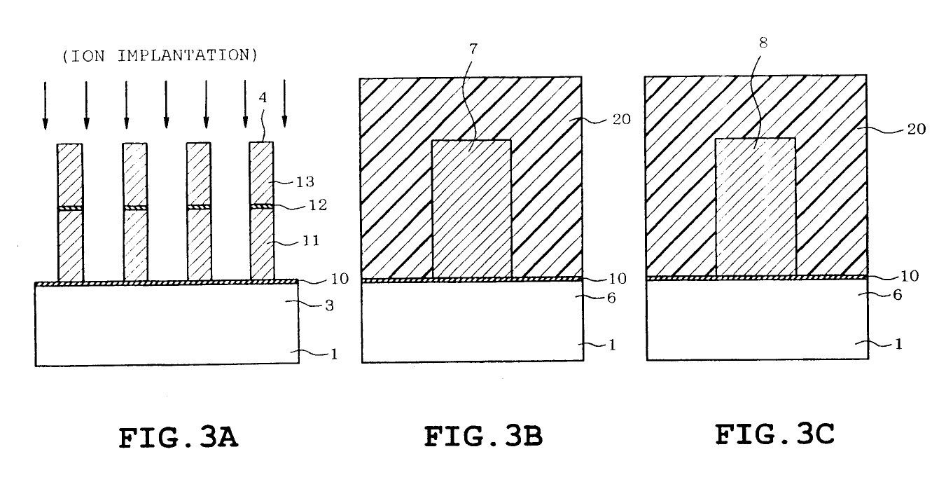

Next, the manufacturing method of the above configuration will be described with reference to FIGS. 3 to 12.

FIGS. 3A to 3C illustrate a photoresist 20 patterned by photolithography process in the peripheral circuit region in order to form the impurity diffusion region 9 constituting the drain/source regions in the transistors of the memory cell region after forming gate electrodes 4, 7 and 8 on the silicon substrate 1. The gate insulating film 10 is formed on the silicon substrate 1 and the gate electrodes 4, 7, and 8 are stacked thereon.

In this case, the gate electrode 4 is formed by stacking the floating gate electrode 11 constituted by a conductive film such as polycrystalline film on the gate insulating film 10 and inter-gate insulating film 12 constituted by ONO (Oxide-Nitride-Oxide) film, or the like, and a control gate electrode 13 constituted by a conductive film such as polycrystalline silicon film. Films such as tungsten (W) may be laminated on the polycrystalline silicon film as required and processed into silicide so that the control gate electrode 13 assumes a stacked configuration having tungsten silicide (WSi) on the upper side thereof.

The gate insulating film 10 is shown to be formed in consistent thickness; however, it is actually formed in the applicable thickness in high-voltage transistors. Also, the gate electrodes 7 and 8 are shown as a continuous object, however, they are actually formed as stacked films, in which a portion of the inter-gate insulating film 12 is opened to virtually place the floating gate electrode 11 and the control gate 13 in a shorted state.

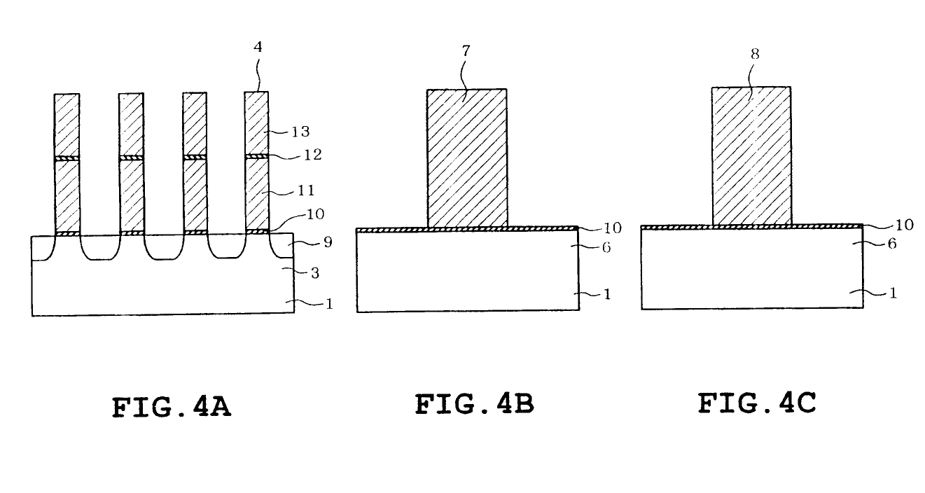

Under the above described condition, impurity diffusion region 9 is formed by selectively doping impurities in the silicon substrate 1 of the memory cell region by using photoresist 20 as a mask. Low-doped impurity diffusion region 9 is formed by introducing impurities such as As (arsenic) and P (phosphorous) by ion implantation for instance for N-channel transistors. Thereafter the photoresist 20 is removed to obtain the configuration indicated in FIGS. 4A to 4C.

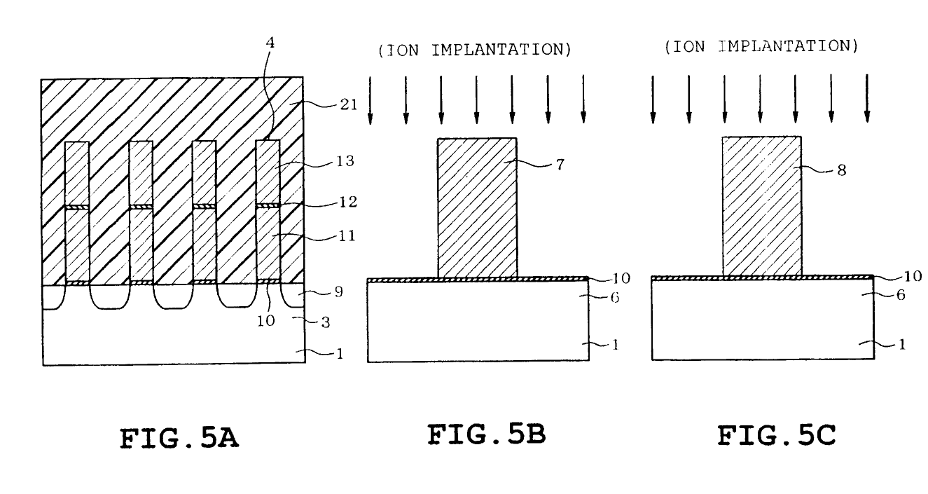

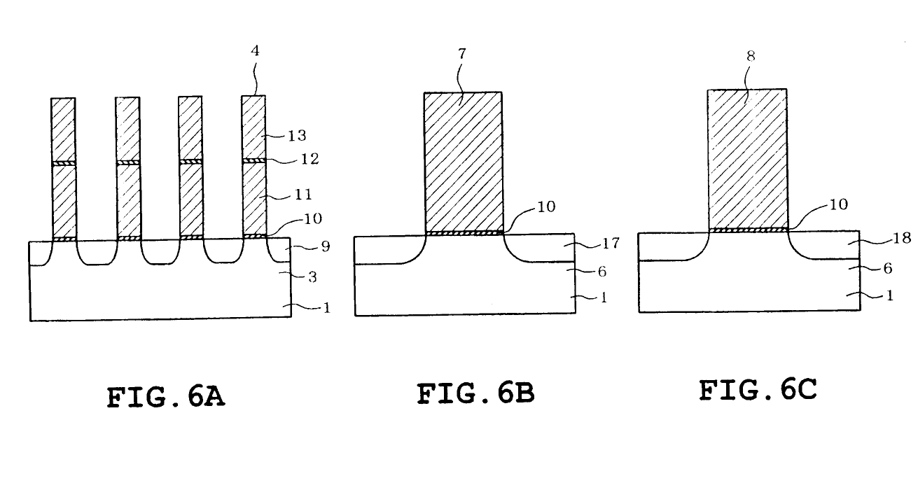

Next, as illustrated in FIGS. 5A to 5C, a photoresist 21 is patterned by lithography process to cover only the memory cell region and ions are implanted in the silicon substrate 1 of the peripheral circuit region to form impurity diffusion regions 17 and 18 constituting the drain/source regions. Similarly, as in the case of the memory cell region, low-doped impurity diffusion regions 17 and 18 are formed by introducing impurities such as As (arsenic) and P (phosphorous) by ion implantation for instance for N-channel transistors. Thereafter, the photoresist 20 is removed to obtain the configuration indicated in FIGS. 6A to 6C.

Formation of respective impurity diffusion regions 9, 17, and 18 for the memory cell region and the peripheral circuit region is not limited to the above sequence but may be carried out so that impurity diffusion regions 17 and 18 of the peripheral circuit region may be formed prior to the memory cell region. Further, ion implantation of impurities may be carried out in a plurality of times.

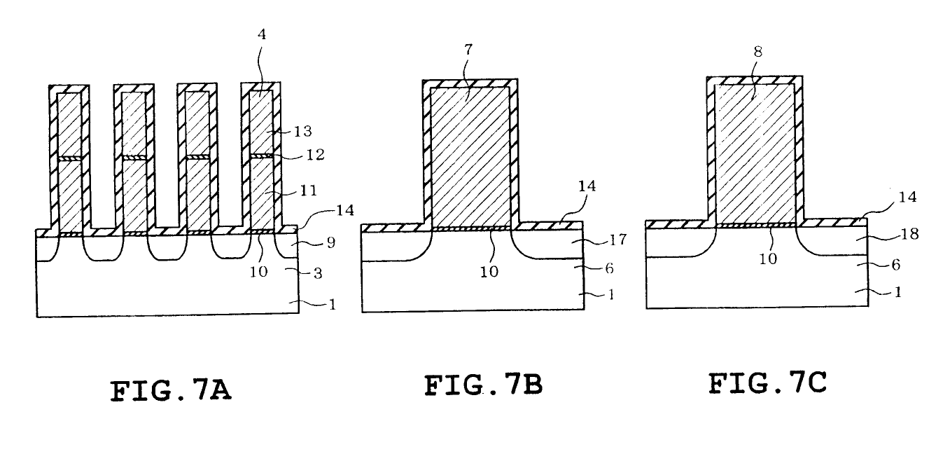

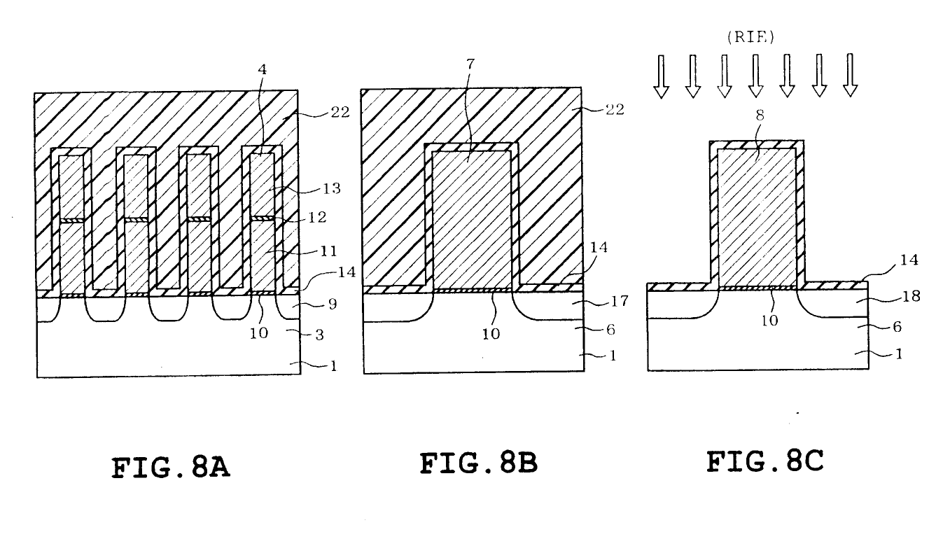

Referring to FIGS. 7A to 7C, the silicon nitride film 14 for forming spacers serving as the first insulating film is deposited over the entire surface of the silicon substrate 1 so as to cover the gate electrodes 4, 7 and 8 respectively. Then, as illustrated in FIG. 8C, spacers 14a are formed on the gate electrodes 8 of the LDD transistors in the peripheral circuit region. As can be seen in FIGS. 8A and 8B, photoresist 22 is patterned by lithography process to cover the non-LDD transistors in the memory cell region and the peripheral circuit region.

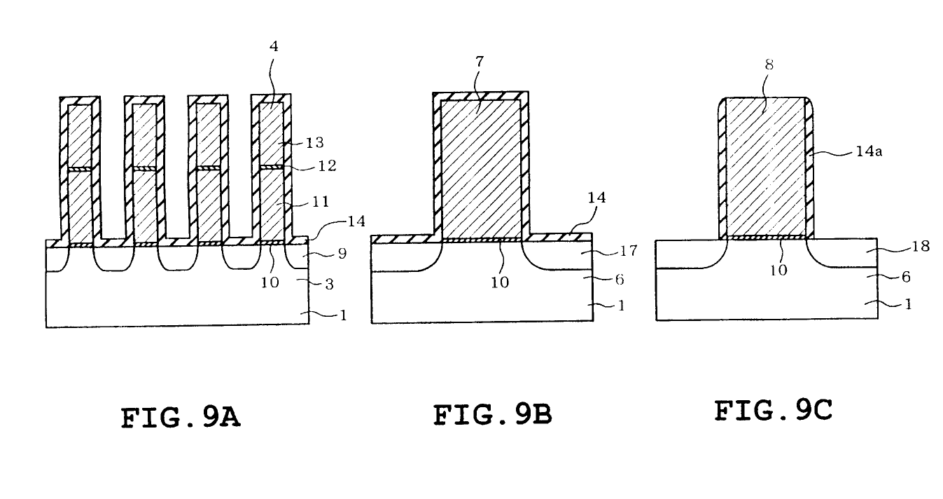

Thereafter, as illustrated in FIG. 8C, spacer 14a is formed by etching away the silicon nitride film 14 except for the sidewall portion of the gate electrode 8 by anisotropic etch such as RIE (Reactive Ion Etching). Then, photoresist 22 is removed to obtain the configuration illustrated in FIGS. 9A to 9C. Spacer 14a is formed only on the sidewalls of the gate electrodes 8 of LDD transistors and silicon nitride film 14 remains as it is or other transistors. Spacer 14a is formed only on gate electrodes 8 of the LDD transistors and other transistors have silicon nitride film 14 remaining thereto.

Thus, silicon substrate 1 is not exposed by RIE process in non-LDD transistors, and the surface of the silicon substrate 1, especially in the memory cell transistors, does not suffer any damages from etching.

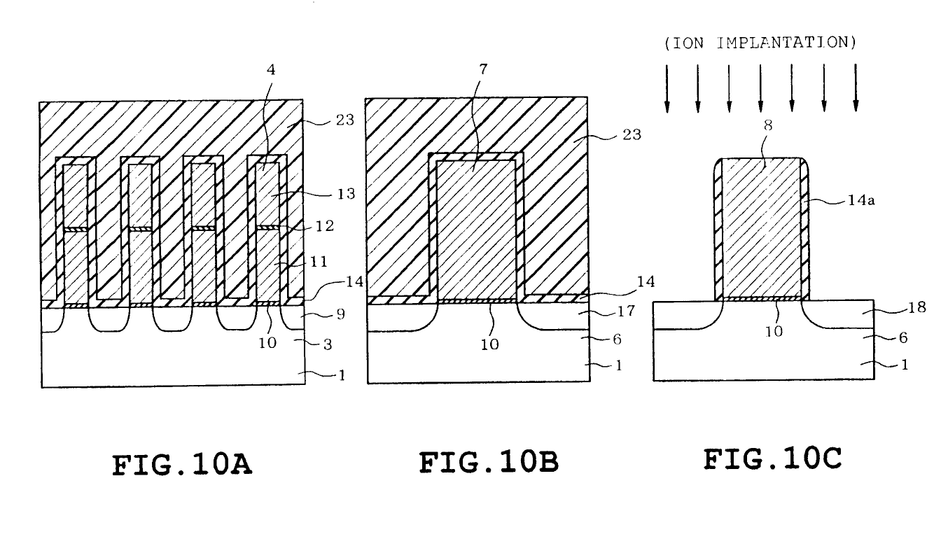

Thereafter, heavily-doped impurity diffusion regions 19 are formed for LDD transistors in the periphery circuit region. As car be seer in FIGS. 10A to 10C, photoresist 23 is patterned by lithography process so as to cover the transistors in the memory cell region and the non-LDD transistors. Then, impurities are introduced by ion implantation at heavy dope in the active region 6 of the silicon substrate 1 of LDD transistors.

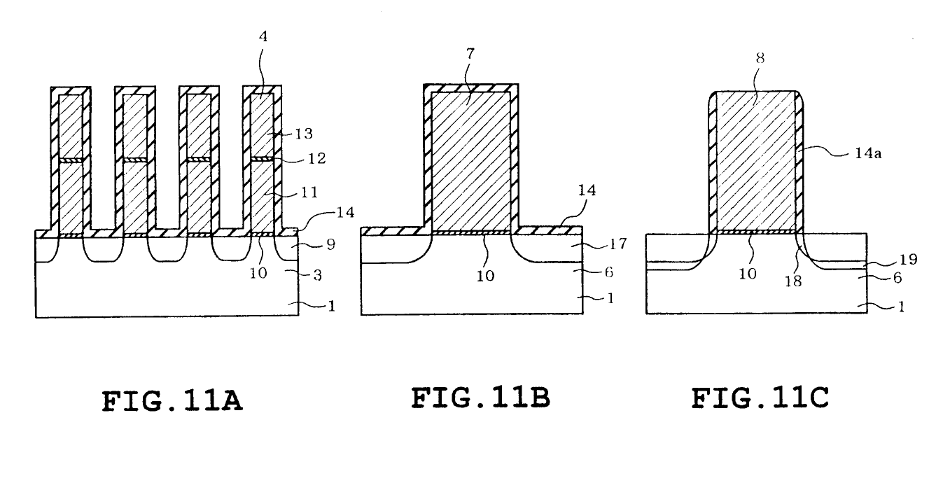

Thereafter, when the photoresist 23 is removed, as illustrated in FIGS. 11A to 11C, the spacer 14a serves as a mask to form heavily-doped impurity diffusion region 19 in a position spaced from the edge of the gate electrode 8; thereby obtaining the LDD structure.

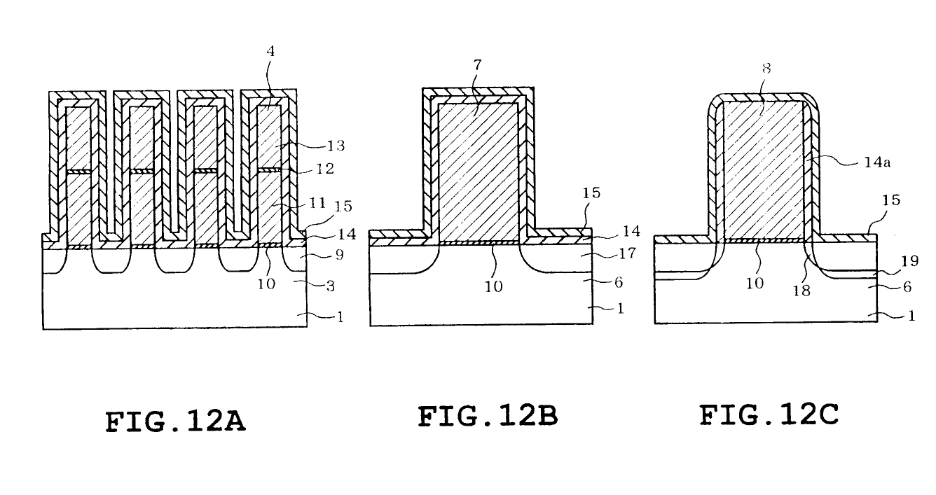

Referring to FIGS. 12A to 12C, barrier silicon nitride film 15 serving as the second insulating film is deposited across the entire surface. The method of manufacture employed in the present disclosure has the following improvements added to the conventional method. Generally, when tungsten silicide film is used as gate electrode material, openings defined between the gate electrodes become narrower due to uneven profile of the gate sidewall caused by thermal processing carried out after gate formation and accelerated deposition of silicon nitride film on the sidewall.

The process flow of the present disclosure deposits silicon nitride film 14 on the sidewalls of the gate electrodes 4 and 7 as well as or the silicon substrate 1 of transistors in the memory cell region and the non LDD transistors in the peripheral circuit region. Thus, as for the deposition rate of the barrier silicon nitride film 15, variation in incubation time between the sidewall (lateral direction) of the gate electrodes 4 and 7 and the silicon substrate 1 (vertical direction) can be eliminated. This prevents increase in deposition rate of the barrier silicon nitride film 15 in the lateral direction and prevents narrowing of the opening defined between the gate electrodes.

By improving the coverage capability in forming the barrier silicon nitride film 15, abnormal diffusion of boron and phosphorous contained in the interlayer insulating film 16 composed of BPSG and PSG towards the gate electrodes 4 and 7 can be prevented while also realizing a process capable of accommodating inconsistencies such as deposition rates of barrier silicon nitride films 15.

The present embodiment provides the following effects. The silicon nitride film 14 for forming the spacer 14a or the sidewall is deposited after processing the gate electrode 8 and thereafter etched by RIE. At this time, anisotropic etch is selectively carried out only on portions taking the LDD structure and transistors not requiring LDD structure such as transistors in the memory cell region are not etched. Thus, variance in incubation time in depositing barrier silicon nitride film 15 car be restrained, which may lead to improvement in coverage capability. Further, since RIE is carried out only on portions requiring LDD structure, no gauging occurs on the silicon substrate 1 surface of other transistors.

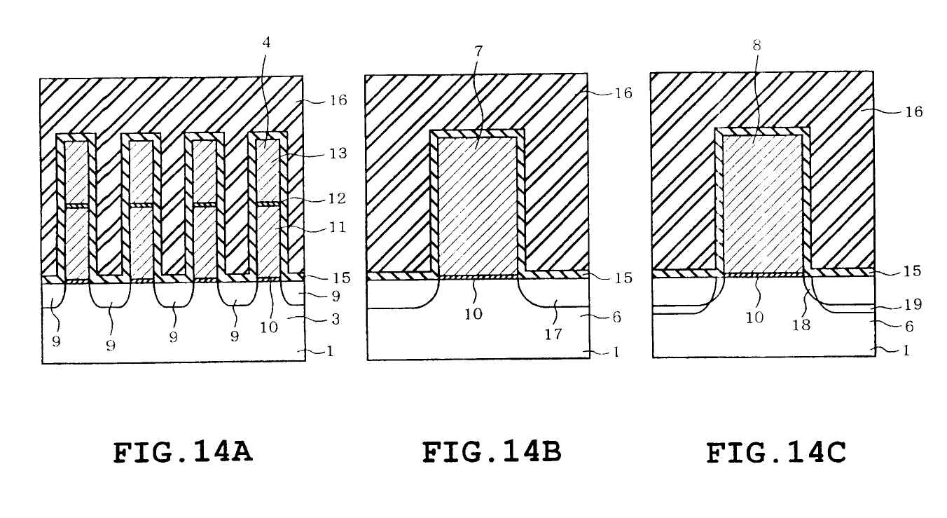

FIGS. 14 to 17 illustrate a second embodiment of the present disclosure which differs from the first embodiment in that, the silicon nitride film 14 for forming spacers serving as the second insulating film and the spacer 14a have been removed. As illustrated in FIGS. 14A to 14C, the silicon nitride film 14 and the spacer 14a have been removed in either configuration.

Under such configuration also, the same effects as the first embodiment can be obtained as well as preventing increased aspect ratio and forming silicon nitride film 15 in consistent thickness especially in the memory cell region; since, in terms of manufacturing steps, the barrier silicon nitride film 15 is formed after removing the silicon nitride film 14 for forming spacers as described afterwards.

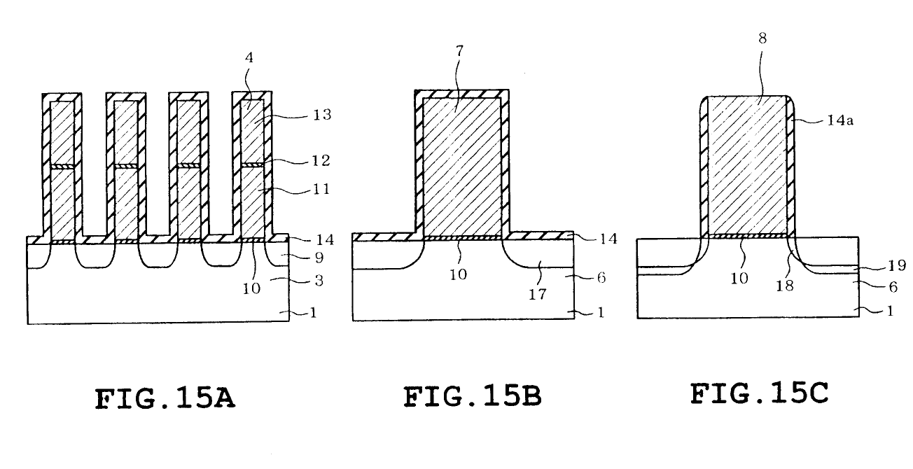

Referring to FIGS. 15 to 17, a description will be given or the manufacturing steps that differ from the first embodiment.

FIGS. 15A to 15C illustrates a state where the manufacturing steps have been carried out up to the state indicated in FIG. 11 of the first embodiment. That is, the heavily-doped impurity diffusion region 19 has been formed by forming the silicon nitride film 14 for forming spacers and selective formation of spacers on transistors requiring LDD structures after forming impurity diffusion regions 9, 17, and 18 constituting the source/drain regions for respective transistors formed in the memory cell region and the peripheral circuit region.

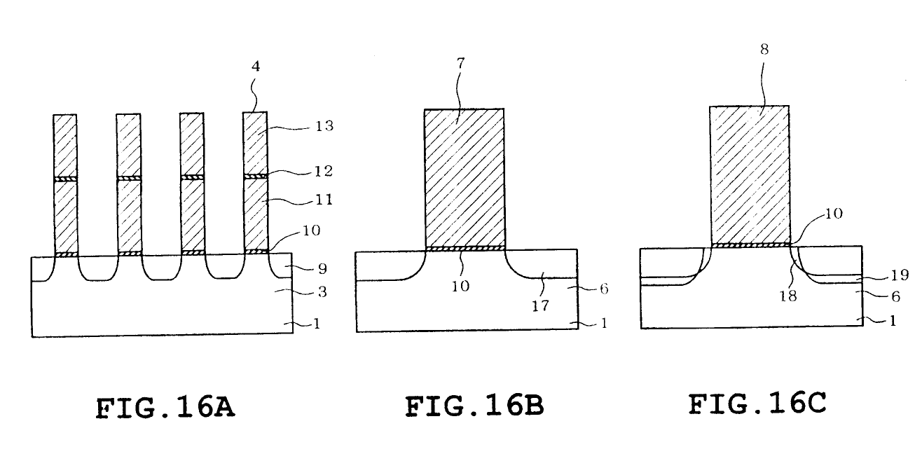

Subsequently, in the present embodiment, the silicon nitride film 14 formed to form the heavily-doped impurity diffusion region 19 and the spacer 14a obtained by processing the silicon nitride film 14 are removed by wet treatment using hot phosphoric acid, or the like as illustrated in FIGS. 16A to 16C.

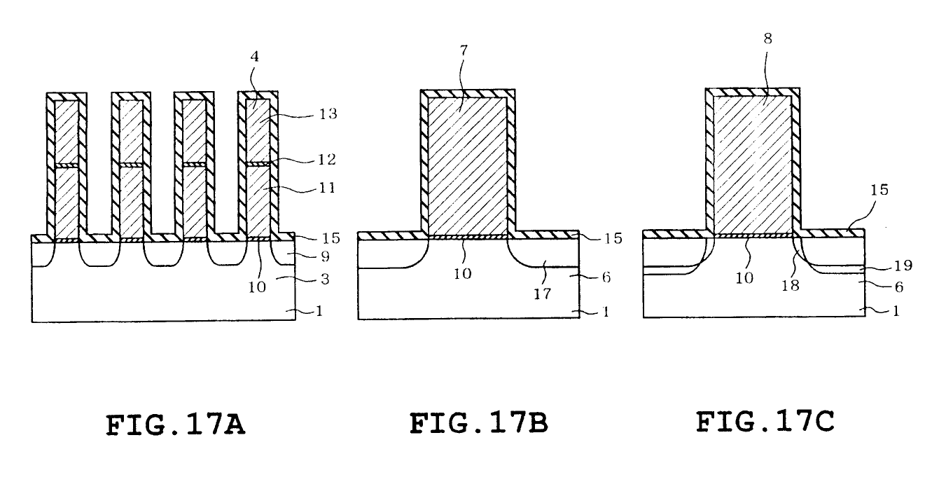

Referring to FIG. 17, the barrier silicon nitride film 15 serving as the second insulating film is deposited in range of 10 nm to 1000 nm. Thereafter, interlayer insulating film 16 composed of silicate glass such as BPSG and PSG is deposited in the range of 10 nm to 1000 nm to obtain the configuration in FIG. 14.

According to the second embodiment described above, as is the case with the first embodiment, by employing the aforementioned method in processing the spacer 14a by RIE on the gate electrode 8 of transistors requiring LDD structure, gauging of silicon substrate 1 can be prevented. Also, by removing the spacer 14a and the silicon nitride film 14 formed in other portions, aspect ratio in portions having strict design rules such as the memory cell region can be reduced, which may lead to improvement of gap fill capability of the interlayer insulating film 16. Also, since spacing between the gate electrodes are increased, coverage of the barrier silicon nitride film 15 can be secured even if the gate sidewall is formed in uneven profile.

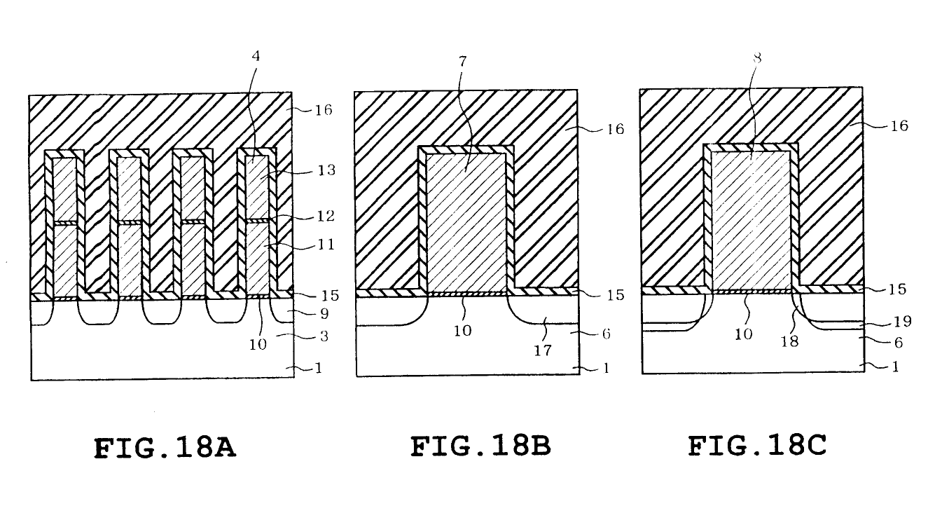

FIGS. 18 to 25 indicate a third embodiment of the present disclosure which differs from the second embodiment in that conventional process is employed in forming the spacer 14a or the sidewall of the gate electrode 8 of the transistor requiring LDD structure and the silicon nitride film processed into the spacer 14a is removed thereafter.

That is, the configuration illustrated in FIGS. 18A to 18C is the same as the configuration of FIG. 14 of the second embodiment but differs from the first embodiment in that the silicon nitride film 14 for forming spacers and the spacer 14a have been removed. Such configuration provides the same effects as the second embodiment as well as preventing increased aspect ratio and forming silicon nitride film 15 in consistent thickness especially in the memory cell region and simplifies the manufacturing step because no lithography process is required to select the area to be processed by RIE since, in terms of manufacturing steps, the barrier silicon nitride film 15 is formed after removing the silicon nitride film 14 for forming spacers as described afterwards.

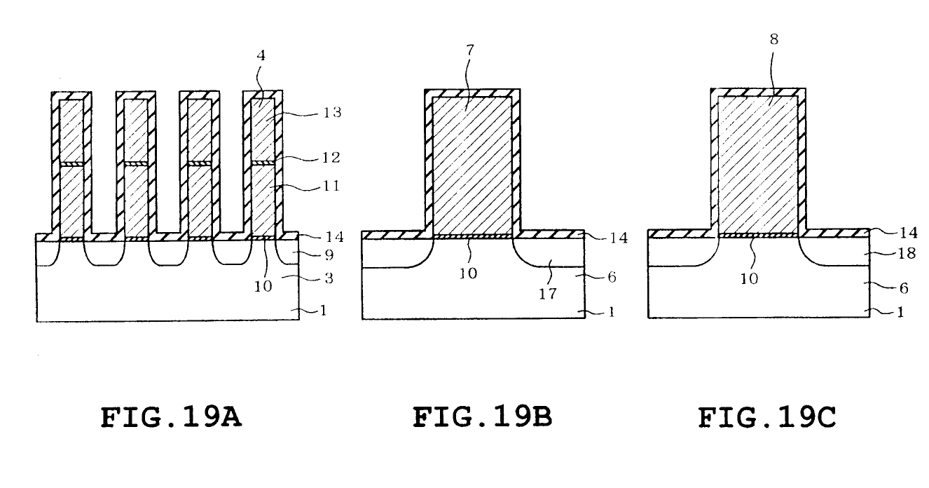

Next, a description will be given on the manufacturing process flow of the above configuration by also referring to FIGS. 19 to 25.

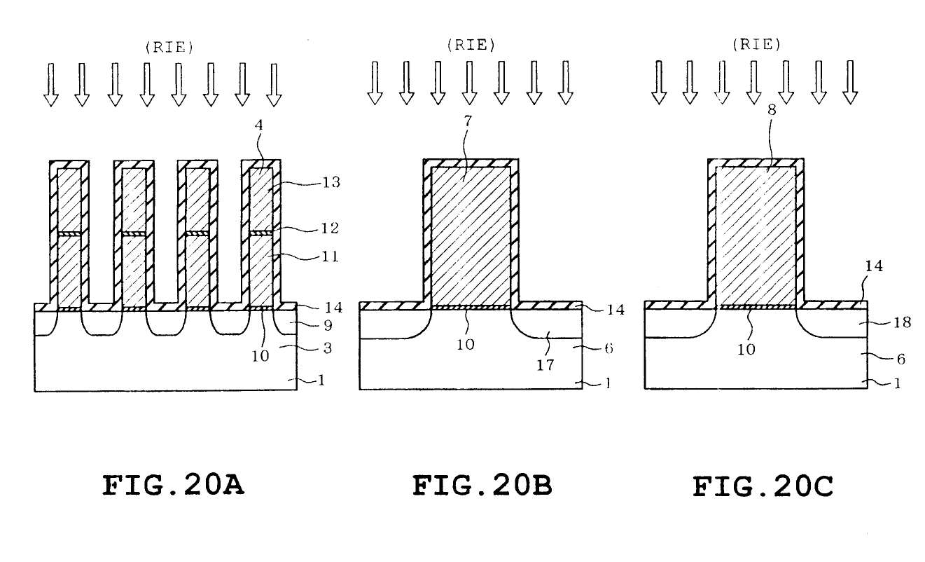

FIGS. 19A to 19C illustrate the state in which the silicon nitride film 14 for forming spacers has been formed that serves as the first insulating film (same as the state shown in FIG. 7) after undergoing the same manufacturing step as the first embodiment. From this state, a resist is patterned by photo lithography process to serve as a mask that covers other portions. Then, instead of carrying out a selective anisotropic etch by RIE process, the entire surface is etched anisotropically by RIE as in the conventional process flow as illustrated in FIGS. 20A to 20C.

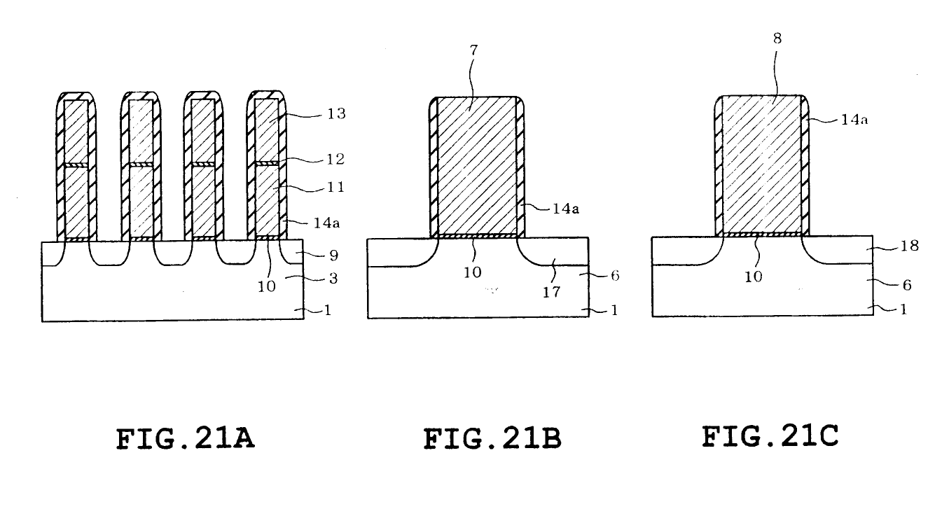

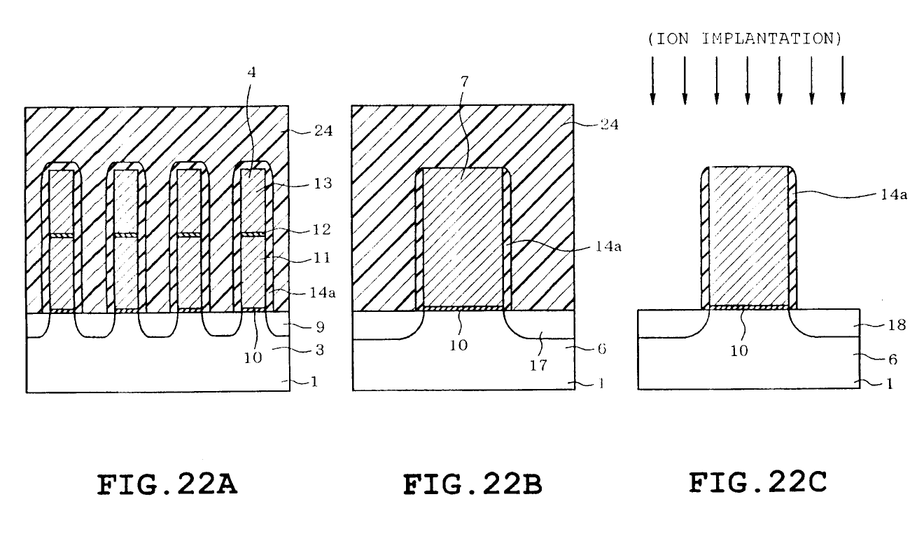

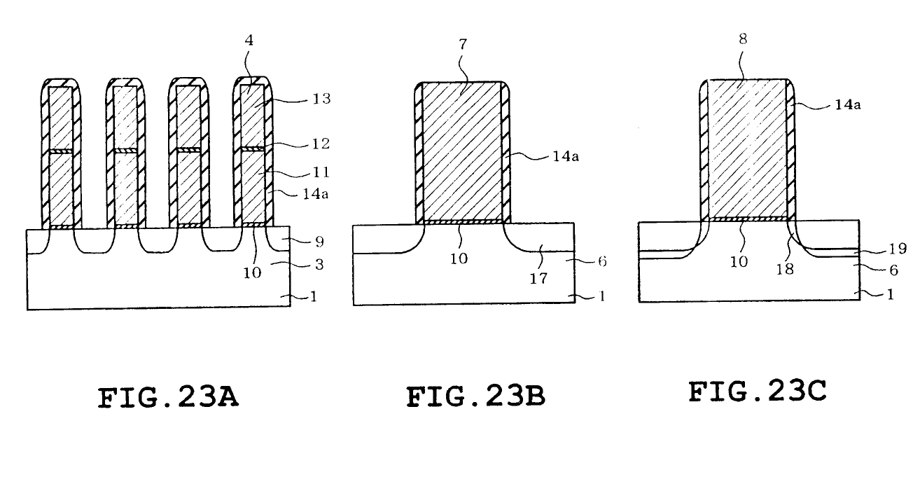

Thus, as illustrated in FIGS. 21A to 21C, spacers 14a are formed on the sidewalls of the gate electrodes 4, 7, and 8 for the respective transistors in the memory cell region and the peripheral circuit region. Next, as illustrated in FIGS. 22A to 22C, the gate electrode 8 portion of the transistor employing the LDD structure is exposed by lithography process and a photoresist 24 is patterned to mask other portions. Ion implantation is carried out by using the spacer 14a formed on the sidewall of the gate electrode 8 to form the heavily-doped impurity diffusion region 19. Thereafter, the photoresist 24 is removed to obtain the configuration illustrated in FIGS. 23A to 23C.

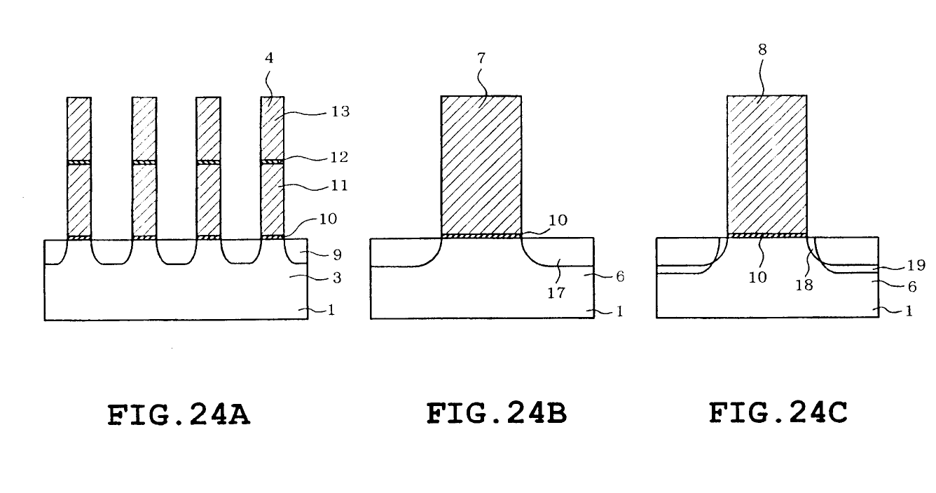

Thereafter, as illustrated in FIGS. 24A to 24C, the spacer 14a of the gate electrode 8 formed and processed to form the heavily-doped impurity diffusion region 19 and the spacers 14a in other portions are removed by wet treatment by hot phosphoric acid, and the like.

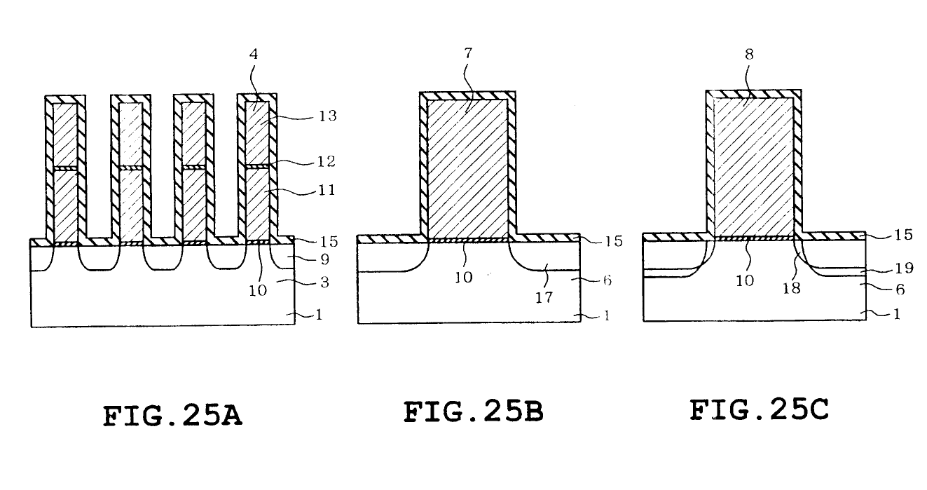

Next, as illustrated in FIGS. 25A to 25C, the barrier silicon nitride film 15 serving as the second insulating film is deposited in range of 10 nm to 1000 nm. Thereafter, interlayer insulating film 16 composed of silicate glass such as BPSG and PSG Is deposited in the range of 10 nm to 1000 nm to obtain the configuration illustrated in FIG. 18.

According to the third embodiment described above, in carrying out the anisotropic etch (RIE) of the spacer 14a for forming the heavily-doped impurity diffusion region of the LDD transistor, spacer forming process is carried out simultaneously without forming photoresist masks for transistors in the memory cell region and the non-LDD transistors in the peripheral circuit region. Ion implantation is carried out selectively in portions taking the LDD structure, whereafter the spacer is removed. Thus, formation of barrier silicon nitride film 15 can be carried out with low aspect ratio in portions subject to strict design rules such as the memory cell region, which may lead to improvement of gap fill capability of the interlayer insulating film 16. Also, since the spacing between the gate electrodes are increased, coverage of the barrier silicon nitride film 15 car be secured ever if the gate sidewall is formed in uneven profile.

The present disclosure is rot limited to the above described embodiments but may be modified or expanded as follows.

The first insulating film constituting the spacer and the second insulating film constituting the barrier are not limited to silicon nitride film but may employ other insulating films.

The present disclosure has been applied to a NAND flash memory, however it may be employed to NOR flash memory and to semiconductor device in general having the LDD structure.

The foregoing description and drawings are merely illustrative of the principles of the present disclosure and are not to be construed in a limited sense. Various changes and modifications will become apparent to those of ordinary skill in the art. All such changes and modifications are seen to fall within the scope of the disclosure as defined by the appended

What is claimed is:

1. A semiconductor device, comprising:
a semiconductor substrate including an upper surface having a memory cell region and a peripheral circuit region;
a memory cell transistor formed in the memory cell region of the semiconductor substrate, including a first gate electrode formed on the upper surface of the semiconductor substrate via a first gate insulating film and a first source/drain regions formed in the upper surface being adjacent to the first gate electrode;
a peripheral transistor, having an LDD (Lightly Doped Drain) structure, formed in the peripheral circuit region of the semiconductor substrate, including a second gate electrode formed on the upper surface of the semiconductor substrate via a second gate insulating film and a second source/drain regions formed in the upper surface being adjacent to the second gate electrode;
a first insulating film formed on a first sidewall of the first gate electrode, the first source/drain regions and a second sidewall of the second gate electrode;
a second insulating film formed on the first sidewall, the first source/drain regions, the second sidewall via the first insulating film, respectively, and
an interlayer insulating film formed on the second insulating film, the interlayer insulating film located adjacent to the first sidewall,
wherein the second insulating film is formed or the second source/drain regions without the first insulating film.

2. The device of claim 1, wherein the first insulating film includes a silicon nitride film.

3. The device of claim 2, wherein the second insulating film includes a silicon nitride film.

4. The device of claim 1, wherein the first insulating film directly contact with the first source/drain regions.

5. The device of claim 4, wherein the second insulating film directly contact with the second source/drain regions.

6. A semiconductor device, comprising:
a semiconductor substrate;
a memory cell transistor formed in a memory cell region of the semiconductor substrate;
a transistor formed in a peripheral circuit region of the semiconductor substrate and having an LDD (Lightly Doped Drain) structure;
wherein the memory cell transistor has a same film structure for an insulating film formed on source/drain regions and an insulating film formed on a gate electrode sidewall; and the transistor having the LDD structure is provided with a spacer insulating film on the gate electrode sidewall.

7. The device of claim 6, wherein the insulating film formed on the source/drain regions of the memory cell transistor and the gate electrode sidewall is a silicon nitride film.

8. A method of manufacturing a semiconductor device, comprising:
forming a gate electrode or a semiconductor substrate for each transistor in a memory cell region having memory cell transistors and a peripheral circuit region having transistors having an LDD structure;
forming a diffusion region constituting source/drain regions or a portion of the semiconductor substrate of each transistor in the memory cell region and the peripheral circuit region;
forming a first insulating film on the semiconductor substrate and a surface of each gate electrode;
forming a spacer on a sidewall of the gate electrode by selectively processing a portion of the first insulating film formed in the transistor having the LDD structure;
forming heavily-doped impurity diffusion region in a portion of the semiconductor substrate of the transistor having the LDD structure;
forming a second insulating film on the semiconductor substrate and the surface of the gate electrode; and
forming an interlayer insulating film.

9. The method of claim 8, wherein the first insulating film is removed prior to forming the second insulating film.

10. The method of claim 9, wherein in forming the spacer or the gate electrode sidewall by selectively processing the first insulating film formed on the transistor having the LDD structure, the spacer is formed or the gate electrode sidewall of the transistor other than the transistor formed on the semiconductor substrate having the LDD structure.
